(19) United States
(12) Patent Application Publication
(10) Pub. No.: US 2026/0344364 A1
(43) Pub. Date: Oct. 29, 2026

(54) OPERATING METHOD OF ELECTRONIC DEVICE CONFIGURED TO MANUFACTURE SEMICONDUCTOR DEVICE

(71) Applicant: Samsung Electronics Co., Ltd., Suwon-si (KR)

(72) Inventors: Hyeonho CHO, Suwon-si (KR); Dongjin PARK, Suwon-si (KR); Ingyun CHUNG, Suwon-si (KR)

(21) Appl. No.: 19/411,624

(22) Filed: Dec. 8, 2025

(30) Foreign Application Priority Data
Apr. 25, 2025 (KR) 10-2025-0054738

(51) Int. Cl. H10P 74/20; G06T 7/00; H10P 72/50

(52) U.S. Cl. CPC H10P 74/203; G06T 7/0004; H10P 72/53; G06T 2207/30148

(57) ABSTRACT

An operating method of an electronic device configured to manufacture a semiconductor device includes receiving an image of the semiconductor device, processing the image by using a first module of the electronic device to generate processing data including information of a first misalignment of first points on the image, and calculating information of a second misalignment of second points on the image from the information of the first misalignment by using a second module of the electronic device to generate a dataset. The dataset includes the information of the first misalignment and the information of the second misalignment.

### CROSS-REFERENCE TO RELATED APPLICATION(S)

This application claims priority under 35 U.S.C. § 119 to Korean Patent Application No. 10-2025-0054738 filed on Apr. 25, 2025 in the Korean Intellectual Property Office, the disclosure of which is incorporated by reference herein in its entirety.

### TECHNICAL FIELD

Implementations of the present disclosure relate to an electronic device, and more particularly, to an operating method of an electronic device configured to manufacture a semiconductor device with reduced error.

### BACKGROUND

A semiconductor device is manufactured using a plurality of semiconductor elements. Some of the plurality of semiconductor elements may be formed at locations defined for interaction. However, depending on process conditions or the characteristics of the semiconductor device, the locations of certain semiconductor elements for the interaction may deviate from their intended positions. A change in the location of some semiconductor elements for the interaction is referred to as misalignment.

In order to reduce the misalignment, a method of measuring the misalignment and modifying a layout of the semiconductor device according to a measurement result may be used. By measuring the misalignment more accurately, errors in the semiconductor manufacturing process may be reduced.

### SUMMARY

Implementations of the present disclosure provide an operating method of an electronic device configured to manufacture a semiconductor device with reduced error.

According to some implementations of the present disclosure, an operating method of an electronic device configured to manufacture a semiconductor device, comprises receiving an image of the semiconductor device, processing the image by using a first module of the electronic device to generate processing data including information of a first misalignment of first points on the image, and calculating information of a second misalignment of second points on the image from the information of the first misalignment by using a second module of the electronic device to generate a dataset. The dataset includes the information of the first misalignment and the information of the second misalignment.

According to some implementations of the present disclosure, an operating method of an electronic device configured to manufacture a semiconductor device, comprises receiving images of the semiconductor device, averaging first misalignment values of the images at a first point of the images by using a first module of the electronic device to generate a second misalignment value of the first point, and calculating a third misalignment value of a second point different from the first point of the images from a plurality of second misalignment values including the second misalignment value by using a second module of the electronic device.

According to some implementations of the present disclosure, an operating method of an electronic device configured to manufacture a semiconductor device, comprises receiving an image of the semiconductor device, processing the image by using a first module of the electronic device to generate processing data including information of a first misalignment of first points on the image, and calculating information of a second misalignment of second points on the images from the information of the first misalignment by using a second module of the electronic device. The image is divided into a plurality of blocks. A block including first points having the information of the first misalignment that is relatively large is set as a block of a tail region. The generating the processing data including the information of the first misalignment includes generating triangles by using the first points in the block of the tail region. And, the calculating the information of the second misalignment includes detecting third points inside the triangles from among the second points in each of the plurality of blocks, performing mapping and interpolation for the third points and the triangles including the third points to calculate information of a third misalignment of the third points, detecting fourth points outside the triangles from among the second points in each of the plurality of blocks, and setting information of a fourth misalignment of each of the fourth points as information of a first misalignment of a first point closest to each of the fourth points.

### BRIEF DESCRIPTION OF DRAWINGS

The above and other objects and features of the present disclosure will become apparent by describing in detail implementations thereof with reference to the accompanying drawings.

FIG. 1 illustrates a semiconductor manufacturing system according to some implementations of the present disclosure.

FIG. 2 is a block diagram illustrating an electronic device according to some implementations of the present disclosure.

FIG. 3 illustrates an example in which semiconductor devices are manufactured on a wafer.

FIG. 4 illustrates an example of a method of calculating overall misalignment according to some implementations of the present disclosure.

FIG. 5 illustrates an example in which a pre-processing module processes captured images.

FIG. 6 illustrates an example of a short-range captured image included in each of the captured images.

FIG. 7 illustrates an example of generating triangles from first points in one block.

FIG. 8 illustrates an example of a method by which a solving module calculates information of a misalignment of second points.

FIG. 9 illustrates an example in which a solving module calculates information of a misalignment of third points and information of misalignment of fourth points.

FIG. 10 illustrates an example of a method by which a post-processing module evaluates a dataset.

FIG. 11 illustrates an example of a graph generated based on information of a misalignment of first and second points of a tail region.

FIG. 12 illustrates an example of color maps generated based on information of a misalignment of first points, and information of misalignment of the first and second points.

FIG. 13 illustrates a dynamic random access memory according to some implementations of the present disclosure.

### DETAILED DESCRIPTION

Below, implementations of the present disclosure will be described in detail and clearly to such an extent that one skilled in the art may carry out implementations of the present disclosure easily.

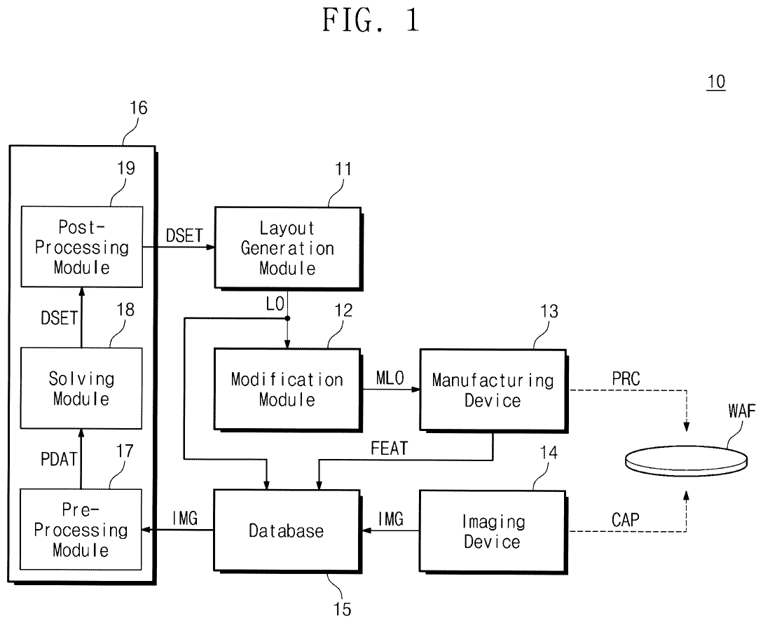

FIG. 1 illustrates a semiconductor manufacturing system 10 according to some implementations of the present disclosure. Referring to FIG. 1, the semiconductor manufacturing system 10 may include a layout generation module 11, a modification module 12, a manufacturing device 13, an imaging device 14, a database 15, and a simulation module 16. The semiconductor manufacturing system 10 may manufacture semiconductor devices based on a wafer WAF.

The layout generation module 11 may generate a layout image LO. For example, the layout generation module 11 may generate or receive circuit-based design information. The layout generation module 11 may generate the layout image LO by arranging standard cells based on the circuit-based design information. Alternatively, the layout generation module 11 may generate the layout image LO by first arranging the standard cells, and then, under user control, modifying the standard cells or arranging specialized cells not included in the standard cells. For example, the layout image LO generated by the layout generation module 11 serves as a design image for manufacturing semiconductor devices, and may include patterns or shapes of pattern edges to be formed in the semiconductor devices.

The layout generation module 11 may receive a dataset DSET from the simulation module 16. The layout generation module 11 may modify the layout image LO based on the dataset DSET. The layout generation module 11 may modify the layout image LO based on the dataset DSET to correct misalignments of the semiconductor devices manufactured on the wafer WAF based on the layout image LO.

The modification module 12 may receive the layout image LO for manufacturing the semiconductor devices from the layout generation module 11. For example, the modification module 12 may generate a modified layout image MLO based on the layout image LO. For example, the modification module 12 may generate the modified layout image MLO based on the layout image LO using a pre-determined algorithm, or a pre-trained machine learning (or a pre-trained deep learning) module, under user control.

The modification module 12 may generate the modified layout image MLO based on the layout image LO by taking into account various factors that arise during the manufacturing of the semiconductor devices. For example, the modification module 12 may generate the modified layout image MLO by incorporating at least process proximity correction (PPC) and optical proximity correction (OPC).

The process proximity correction may correct distortions occurring during a process (e.g., an etch process) due to various factors, including characteristics of materials for performing the process, characteristics of materials to which the process is applied, characteristics of photoresist patterns, and the like. For example, the optical proximity correction may correct distortions occurring in the photoresist patterns due to various factors, including a characteristic of a light source, a characteristic of a photoresist, locational relationships of patterns formed in the light source and the photoresist, and the like, in the process of generating a photomask for manufacturing of the semiconductor device.

The manufacturing device 13 may receive the modified layout image MLO from the modification module 12. The manufacturing device 13 may apply the processes PRC to the wafer WAF based on the modified layout image MLO. For example, processes PRC may include etching, deposition, growth, planarization, and the like. When the processes PRC are applied to the wafer WAF, the semiconductor devices may be formed on the wafer WAF.

The imaging device 14 may capture CAP an image of the semiconductor devices formed on the wafer WAF to generate a captured image IMG. For example, the imaging device 14 may include a scanning electron microscope (SEM).

The database 15 may receive a layout image LO from the layout generation module 11, and receive the captured image IMG of the semiconductor devices manufactured based on the layout image LO from the imaging device 14. The database 15 may store and manage the layout image LO and the corresponding captured image IMG in pairs. In some implementations, the database 15 may separately store the layout image LO received from the layout generation module 11 or the captured image IMG received from the imaging device 14, or may store only one of the layout image LO and the captured image IMG.

The simulation module 16 may receive the captured images IMG from the database 15. The simulation module 16 may measure and predict misalignments of the semiconductor devices on the wafer WAF based on the captured images IMG. The simulation module 16 may include a pre-processing module 17, a solving module 18, and a post-processing module 19.

The pre-processing module 17 may extract information of the misalignment measured by the imaging device 14 from the captured images IMG. An output of the pre-processing module 17 may be provided to the solving module 18 as processed data PDAT. The processed data PDAT may include information of the misalignment, and may further include additional information, for example.

The solving module 18 may predict information of additional misalignment from the information of the measured misalignment. An output of the solving module 18 may be provided to the post-processing module 19 as a dataset DSET. The dataset DSET may include the information of the measured misalignment and the information of the predicted misalignment, and may further include additional information, for example.

The post-processing module 19 may evaluate the information of the measured misalignment and the information of the predicted misalignment. The post-processing module 19 may display the result of the evaluation to the user. In some implementations, the post-processing module 19 may perform scoring by assigning a score to the evaluation result. The post-processing module 19 may provide the dataset DSET to the layout generation module 11. The scores of the evaluation result may be provided to the layout generation module 11 either as additional information within the dataset DSET or together with the dataset DSET.

For example, the layout generation module 11, the modification module 12, and the simulation module 16 may be implemented as software executed by a processor, as a processor configured to perform the functions, or a combination of hardware and software configured to perform the functions.

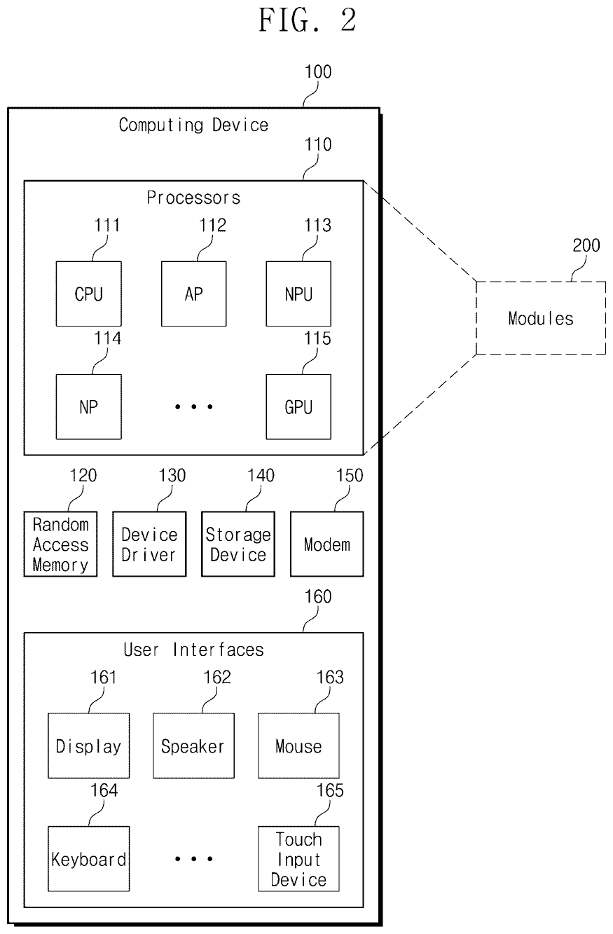

FIG. 2 is a block diagram illustrating a computing device 100 (or an electronic device) according to some implementations of the present disclosure. Referring to FIG. 2, the computing device 100 (or the electronic device) may be configured to support the manufacturing of semiconductor devices. The computing device 100 (or the electronic device) may perform some of the functions or the processes of the semiconductor manufacturing system 10 described with reference to FIG. 1. The computing device 100 (or the electronic device) may include processors 110, a random access memory 120, a device driver 130, a storage device 140, a modem 150, and user interfaces 160.

The processors 110 may include, for example, at least one general-purpose processor such as a central processing unit (CPU) 111, an application processor (AP), and the like. The processors 110 may also include at least one special-purpose processor, such as a neural processing unit (NPU) 113, a neuromorphic processor (NP) 114, a graphics processing unit (GPU) 115, and the like. The processors 110 may include two or more processors of the same kind.

At least one of the processors 110 may execute modules 200. For example, at least some modules of the modules 200 may be modules that are learned based on machine learning or deep learning, and at least some other modules of the modules 200 may be modules that operate based on a pre-determined algorithm.

The random access memory 120 may be used as an operating memory of the processors 110, and may be used as a main memory or a system memory of the computing device 100. The random access memory 120 may include a volatile memory such as a dynamic random access memory (DRAM), a static random access memory (SRAM), or a non-volatile memory such as a phase change random access memory, a ferroelectric random access memory, a magnetic random access memory, or a resistive random access memory.

The device driver 130 may control peripheral devices such as the storage device 140, the modem 150, the user interfaces 160, and the like according to the request of the processors 110. The storage device 140 may include a fixed storage device such as a hard disk drive, a solid state drive, and the like, or a removable storage device such as an external hard disk drive, external solid state drive, removable memory card, and the like.

The modem 150 may provide remote communication with an external device. The modem 150 may perform a wireless or wired communication with the external device. The modem 150 may communicate with the external device via at least one of various communication types such as Ethernet, Wi-Fi, LTE, 5G mobile communication, and the like.

The user interfaces 160 may receive information from the user and provide information to the user. The user interfaces 160 may include at least one user output interface such as a display 161, a speaker 162, and the like, and at least one user input interface such as a mouse 163, a keyboard 164, a touch input device 165, and the like.

Instructions (or codes) of the modules 200 may be received via the modem 150 and stored in the storage device 140. The instructions (or the codes) of the modules 200 may be stored in the removable storage device and coupled to the computing device 100. The instructions (or the codes) of the modules 200 may be loaded from the storage device 140 into the random access memory 120 and then executed.

For example, the modules 200 may include at least one of the layout generation module 11, the modification module 12, and the simulation module 16 described with reference to FIG. 1. The layout generation module 11, the modification module 12, and the simulation module 16 may be implemented or executed in different electronic devices. Two or more of the layout generation module 11, the modification module 12, and the simulation module 16 may be implemented or executed in one electronic device.

For example, the database 15 may be implemented as a storage device 140 as a component of the computing device 100, or as a remote device communicating with the computing device 100 via the modem 150.

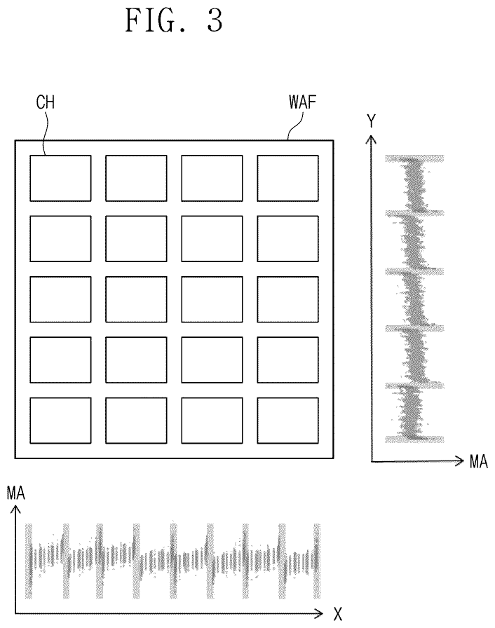

FIG. 3 illustrates an example in which semiconductor devices are manufactured on a wafer WAF. Referring to FIGS. 1 and 3, the manufacturing device 13 may manufacture a plurality of semiconductor chips CH on the wafer WAF. Each of the semiconductor chips CH may be manufactured with a plurality of semiconductor elements. Some materials of the plurality of semiconductor elements may be manufactured at locations where they may interact. If the locations of some materials vary due to process or material conditions, misalignments MA may occur.

In FIG. 3, X and MA illustrate information of the misalignment MA along the X-axis of the wafer WAF. For example, the information of the misalignment MA may represent the magnitude of the misalignment as a distance value or a normalized distance value.

In FIG. 3, Y and MA illustrates information of the misalignment MA along the Y-axis of the captured image IMG. For example, the information of the misalignment MA may represent the magnitude of the misalignment as a distance value or a normalized distance value.

For example, the information of the misalignment MA may be obtained through sampling. For example, the imaging device 14 may capture images at selected points (e.g., a set of first points) where the misalignment may occur (or may be measured) and measure the information of the misalignment MA.

Therefore, the information of the misalignment MA may not accurately represent misalignment occurring in actual semiconductor devices. In order to estimate misalignment occurring in the actual semiconductor devices, a method may be employed in which machine learning-based fitting functions are set, and information about the overall misalignment is inferred using the machine learning-based fitting functions.

However, the information of the misalignment MA of the semiconductor devices may include a tail region with a trend different from that of other portions. The tail region may result from thermal expansion at edge portions of the semiconductor devices. A trend of information of the misalignment MA in the tail region may be different from a trend of information of misalignment MA in other regions. Thus, a method of inferring information about the overall misalignment based on machine learning may have low accuracy in the tail region.

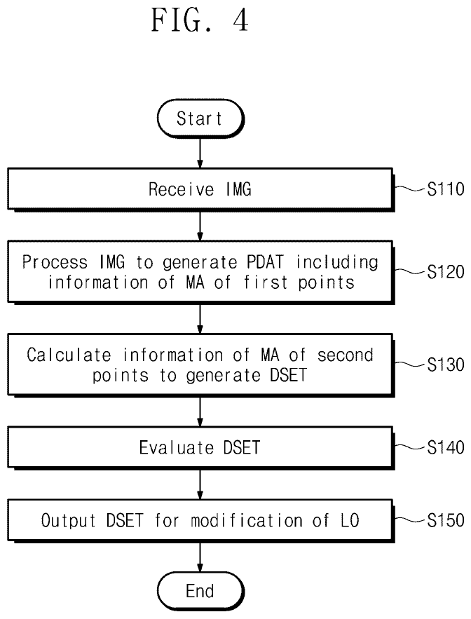

FIG. 4 illustrates an example of a method of calculating overall misalignment according to some implementations of the present disclosure. Referring to FIGS. 1 and 4, in step S110, the pre-processing module 17 of the simulation module 16 may receive the captured image IMG. For example, the pre-processing module 17 may receive a plurality of captured images IMG from the database 15.

Each of the plurality of captured images IMG may include short-range captured images captured by the imaging device 14 to measure information of the misalignment MA of the semiconductor devices on the wafer WAF. For example, there may be points (e.g., total points) that need to be captured in order to measure the overall misalignment MA in a particular region on the semiconductor devices.

Each of the plurality of captured images IMG may be used to measure information of misalignment MA at first points, excluding a set of second points (e.g., unsampled points) from among all points. For example, the plurality of captured images IMG may be used to measure the information of the misalignment MA at the same first points of the same location on the wafer WAF.

In step S120, the pre-processing module 17 may process the captured images IMG to generate processed data PDAT including the information of the misalignment MA at the first points. For example, the processed data PDAT may further include information of triangles (described below) as additional information. The processed data PDAT may be provided to the solving module 18.

In step S130, the solving module 18 may calculate information of misalignment MA at the second points to generate the dataset DSET. For example, the solving module 18 may calculate the information of the misalignment MA at the second points based on the information of the misalignment MA at the first points. Accordingly, the solving module 18 may calculate the information of the overall misalignment MA. The dataset DSET may be provided to the post-processing module 19.

In step S140, the post-processing module 19 may evaluate the dataset DSET. For example, the post-processing module 19 may process the dataset DSET to generate verification information for verifying the quality of the information of the overall misalignment MA.

In step S150, the post-processing module 19 may provide the dataset DSET to the layout generation module 11 for modification of the layout image LO. In some implementations, the post-processing module 19 may provide the dataset DSET and the verification information to the layout generation module 11. The dataset DSET may be used by the layout generation module 11 to modify the layout image LO. The modified layout image MLO may be used to manufacture the semiconductor devices on the wafer WAF.

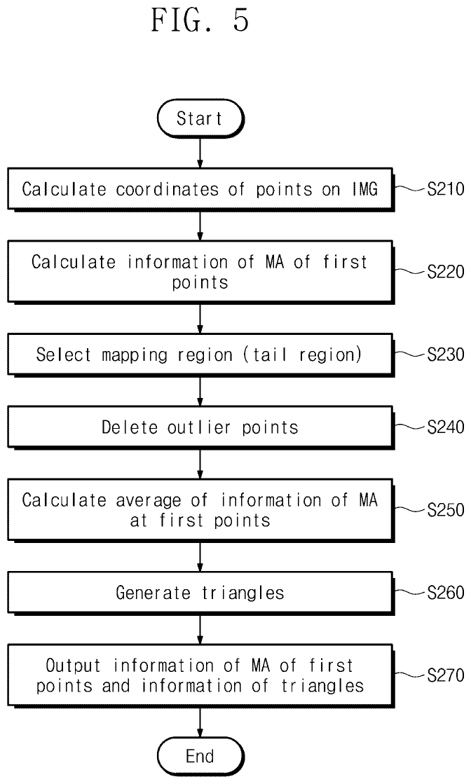

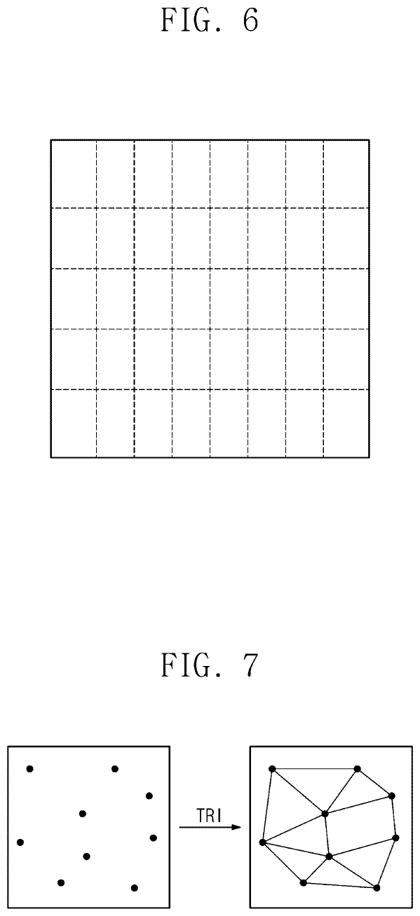

FIG. 5 illustrates an example in which the pre-processing module 17 processes the captured images IMG. FIG. 6 illustrates an example of a short-range captured image included in each of the captured images IMG.

Referring to FIGS. 1, 5, and 6, in step S210, the pre-processing module 17 may calculate coordinates of points on the captured images IMG. For example, as illustrated in FIG. 6, each short-range captured image may be divided into a plurality of blocks. The sizes of the plurality of blocks may be the same. The pre-processing module 17 may calculate coordinates of the first points at which the misalignment MA is measured and coordinates of the second points (e.g., unsampled points) at which the misalignment MA is not measured in each block.

For example, FIG. 1may not depict locations of the first points and the second points. The locations of the first points and the second points may be arranged in an array form, or may be arranged in a random form.

In step S220, the pre-processing module 17 may calculate information of the misalignment MA at the first points. For example, the pre-processing module 17 may calculate information of the misalignment MA at the first points in each of the captured images IMG, based on images of the first points included in the captured images IMG. For example, the pre-processing module 17 may calculate the information of the misalignment MA based on a distance between a target location of each of the first elements and a target location of each of second elements that are arranged to interact. The second elements may be different from the first elements.

In step S230, the pre-processing module 17 may select a mapping region (or a tail region). For example, from among the first points in the captured images IMG, the first points having relatively large misalignment MA value may be selected as the mapping region (or the tail region). For example, the mapping region (or the tail region) may be selected in units of blocks. For example, blocks including first points having information of a relatively large misalignment MA value may be selected from among blocks of the captured images IMG as the mapping region (the tail region).

For example, the criterion of being relatively large may be determined by a first threshold. For example, a block in which one or more first points have a misalignment MA value is greater than the first threshold may be selected as the mapping region (or the tail region). In some implementations, a block in which the information of the average misalignment MA of the first points is greater than the first threshold may be selected as the mapping region (or the tail region).

For example, the criterion of being relatively large may be determined by the first threshold and a second threshold. For example, a block in which the number of first points at which a misalignment MA value exceeds the first threshold is greater than the second threshold may be selected as the mapping region (or the tail region).

In step S240, the pre-processing module 17 may delete outlier points. For example, the pre-processing module 17 may identify certain first points in which misalignment MA is out of a normal range (e.g., greater than or equal to a third threshold) from among the first points as the outlier points. The pre-processing module 17 may delete the information of the misalignment MA at the outlier points.

For example, the outlier points whose information of the misalignment MA is deleted, may be either excluded from the subsequent process or included in the set of second points.

In step S250, the pre-processing module 17 may calculate an average of the information of the misalignment MA at the first points. For example, the pre-processing module 17 may calculate an average of the information of misalignment MA at each of the first points included in the captured images IMG as information of a unique misalignment MA.

For example, each of the captured images IMG may include, e.g., three first points, such as a first point A, a first point B, and a first point C. The pre-processing module 17 may calculate an average of the information of the misalignment MA at first points A included in the multiple captured images IMG as the information of a unique misalignment MA at the first point A.

Similarly, the pre-processing module 17 may calculate an average of the information of the misalignment MA at first points B included in the multiple captured images IMG as the information of a unique misalignment MA at the first point B. The pre-processing module 17 may calculate an average of the information of the misalignment MA at first points C included in the multiple captured images IMG as the information of a unique misalignment MA at the first point C.

For example, each of the first points included in the captured images IMG may have the information of the misalignment MA corresponding to the number of the captured images IMG. When the average of the information of the misalignment MA at the first points is calculated as the information of the unique misalignment MA, each of the first points included in the captured images IMG may have the information of a unique misalignment MA.

In step S260, the pre-processing module 17 may generate triangles. For example, the pre-processing module 17 may generate triangles for the first points in each block based on a Delaunay triangulation.

FIG. 7 illustrates an example of generating triangles from first points in one block. Referring to FIG. 7, for example, the Delaunay triangulation TRI may require that the sum of the two largest interior angles of the two adjacent triangles be less than or equal to π. According to the Delaunay triangulation TRI, triangles close to equilateral triangles may be generated.

Referring again to FIGS. 1 and 5, in step S270, the pre-processing module 17 may output the information of the misalignment MA at the first points and the information of the triangles. The information of the misalignment MA at the first points may be the information of the unique misalignment MA calculated in step S250. The information of the triangles may be included in the additional information described with reference to FIG. 1.

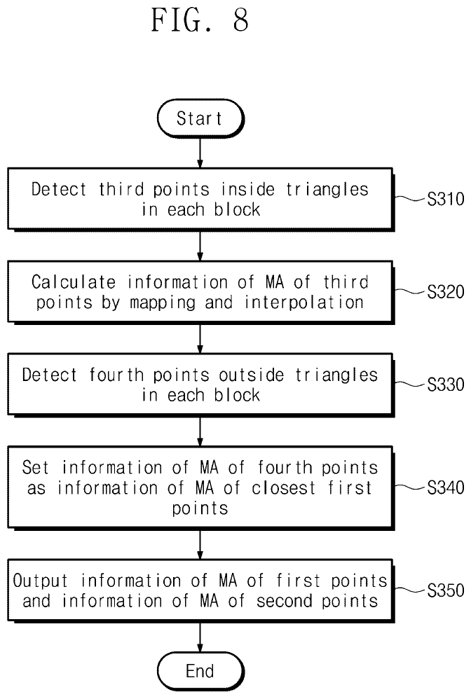

FIG. 8 illustrates an example of a method in which the solving module 18 calculates information of the misalignment MA at the second points. Referring to FIGS. 1 and 8, in step S310, the solving module 18 may detect third points inside the triangles in each block. For example, the third points may be points located inside the triangles from among the second points.

In step S320, the solving module 18 may calculate information of a misalignment MA at the third points by a mapping and an interpolation.

In step S330, the solving module 18 may detect fourth points outside the triangles in each block. The fourth points may be points located outside of the triangles from among the second points.

In step S340, the solving module 18 may set information of a misalignment MA of the fourth points as the information of the misalignment MA at the closest first points.

In step S350, the solving module 18 may output the information of the misalignment MA at the first points and the information of the misalignment MA at the second points. For example, the information of the misalignment MA at the second points may include the information of the misalignment MA at the third points and the information of the misalignment MA at the fourth points. The solving module 18 may output information of the misalignment MA as the dataset DSET.

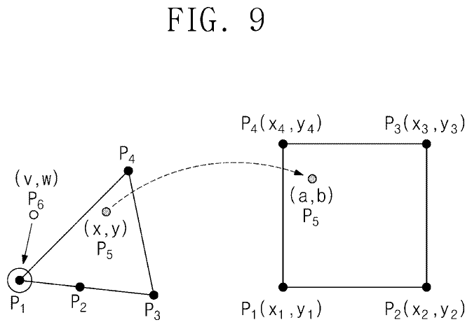

FIG. 9 illustrates an example in which the solving module 18 calculates the information of the misalignment MA at the third points and the information of the misalignment MA at the fourth points. Referring to FIGS. 1, 8, and 9, a first place point P₁, a third place point P₃, and a fourth place point P₄ may be first points forming a triangle including three vertices. The solving module 18 may generate a second place point P₂ for mapping. The second place point P₂ may be referred to as a dummy point.

The solving module 18 may calculate the information of the misalignment MA at the second place point P₂ by interpolating the information of the misalignment MA at the first place point P₁ and the information of the misalignment MA at the third place point P₃, based on a distance between the second place point P₂ and the first place point P₁, and a distance between the second place point P₂ and the third place point P₃.

The solving module 18 may perform an isoparametric mapping on the triangle formed by the first place point P₁, the second place point P₂, the third place point P₃, and the fourth place point P₄ to convert the triangle into a quadrilateral (e.g., a square).

The fifth place point P₅ may correspond to the third point inside the triangle and have coordinates of (x, y). When the isoparametric mapping is performed, the coordinates of the fifth place point P₅ may be mapped to (a, b) by calculating a solution of a nonlinear equation in Equation 1.

x=(1−a)(1−b)x₁+a(1−b)x₂+abx₃+(1−a)bx₄

y=(1−a)(1−b)y₁+a(1−b)y₂+aby₃+(1−a)by₄ [Equation 1]

In Equation 1, (x₁, y₁) are coordinates of P₁, (x₂, y₂) are coordinates of P₂, (x₃, y₃) are coordinates of P₃, and (x₄, y₄) are coordinates of P₄.

The information of the misalignment MA at the fifth place point P₅ obtained by Equation 1 may be calculated by performing a bilinear interpolation. The bilinear interpolation may be performed according to Equation 2.

MA5=q(βMA1+αMA4)+p(βMA2+αMA3) [Equation 2]

In Equation 2, MA₁ is the information of the misalignment MA at the first place point P₁, MA₂ is the information of the misalignment MA at the second place point P₂, MA₃ is the information of the misalignment MA at the third place point P₃, MA₄ is the information of the misalignment MA at the fourth place point P₄, and MA₅ is the information of the misalignment MA at the fifth place point P₅.

The parameters used in Equation 2 may be summarized in Equation 3.

α=h₁/(h₁+h₂)

β=h₂/(h₁+h₂)

p=w₁/(w₁+w₂)

q=w₂/(w₁+w₂) [Equation 3]

In Equation 3, h₁ is a length of a vertical height between the first place point P₁ and the fifth place point P₅, h₂ is a length of a horizontal distance between the fourth place point P₄ and the fifth place point P₅, w₁ is a length of a vertical height between the third place point P₃ and the fifth place point P₅, and w₂ is a length of a horizontal distance between the second place point P₂ and the fifth place points P₅.

According to Equations 2 and 3, the information of the misalignment MA at the fifth place point P₅ corresponding to the third point may be calculated. That is, the information of the misalignment MA at the fifth place point P₅ may be calculated without measuring the information of the misalignment MA at the fifth place point P₅.

The sixth place point P₆ may include coordinates of (v, w) and correspond to a fourth point outside the triangle. Therefore, the solving module 18 may set the information of the misalignment MA at the sixth place point P₆ to be the same as the information of the misalignment MA at the first place point P₁, which is the first point closest to the sixth place point P₆. That is, the information of the misalignment MA at the sixth place point P₆ may be calculated without measuring the information of the misalignment MA at the sixth place point P₆.

As described above, according to some implementations of the present disclosure, the simulation module 16 may measure the information of the misalignment MA at the first points, and calculate the information of the misalignment MA at the second points based on the information of the misalignment MA at the first points.

Identifying the tendency of the information of the misalignment MA at the first points by machine learning may involve both an error of the function itself and an error introduced by a user in setting the function. However, according to some implementations of the present disclosure, the simulation module 16 may utilize mapping and interpolation to obtain the information of the misalignment MA at all points, including the first points and the second points. Thus, the misalignment MA may be measured, predicted, and modified with reduced error.

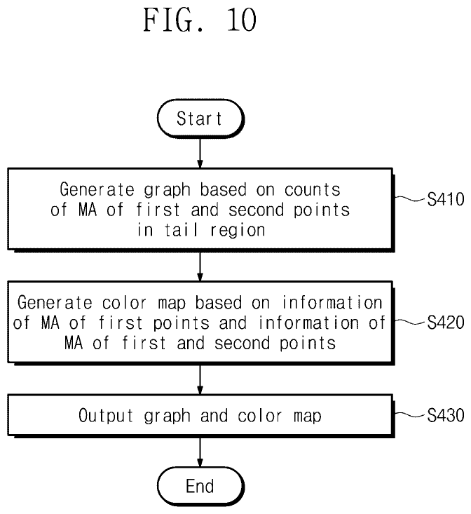

FIG. 10 illustrates an example of a method by which the post-processing module 19 evaluates the dataset DSET. Referring to FIGS. 1 and 10, in step S410, the post-processing module 19 may generate a graph based on the information (e.g., values) of the misalignment MA at the first and second points in the tail region.

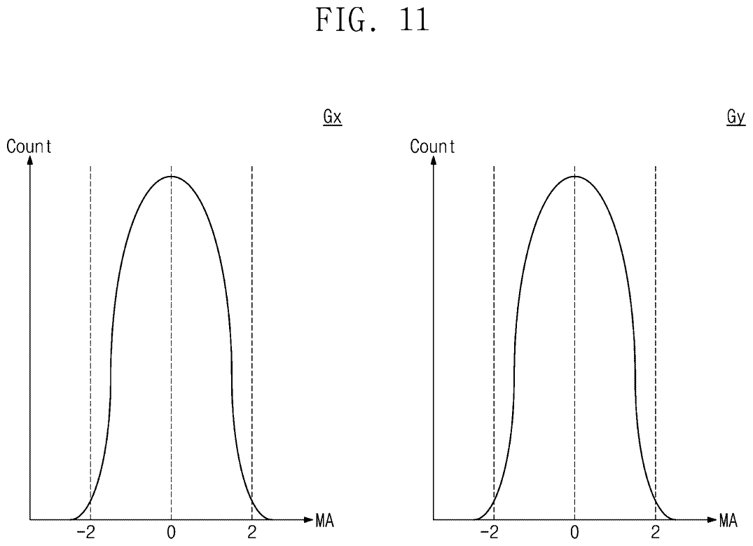

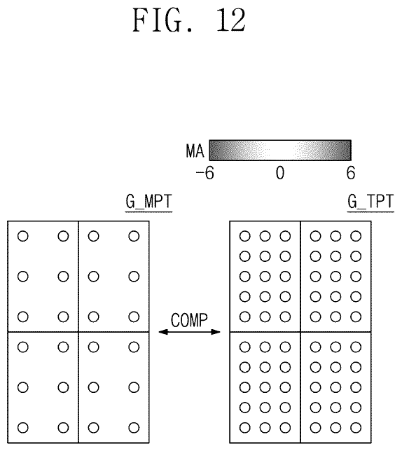

FIG. 11 illustrates an example of the graph generated based on the information of the misalignment MA at the first and second points in the tail region. In FIG. 11, the horizontal axis indicates the information of the misalignment MA, and the vertical axis illustrates a count (e.g., counted values or the numbers) of the first and second points in the tail region. The horizontal axis and the vertical axis may be referred to as X-axis and Y-axis, respectively.

For example, a graph Gx corresponding to the X-axis and a graph Gy corresponding to the Y-axis are illustrated. For example, the count of the first and second points in the tail region may have a Gaussian shape around the point where the information of the misalignment MA is ‘0’, but this is merely an example.

According to the graph illustrated in FIG. 11, the dataset DSET may be easily evaluated by comparing the number of the first and second points in the tail region having the information of the misalignment MA outside a threshold range (e.g., a range between +2 and −2),.

Referring back to FIG. 10, in step S420, the post-processing module 19 may generate a color map based on the information of the misalignment MA at the first points, and the information of the misalignment MA at the first and second points.

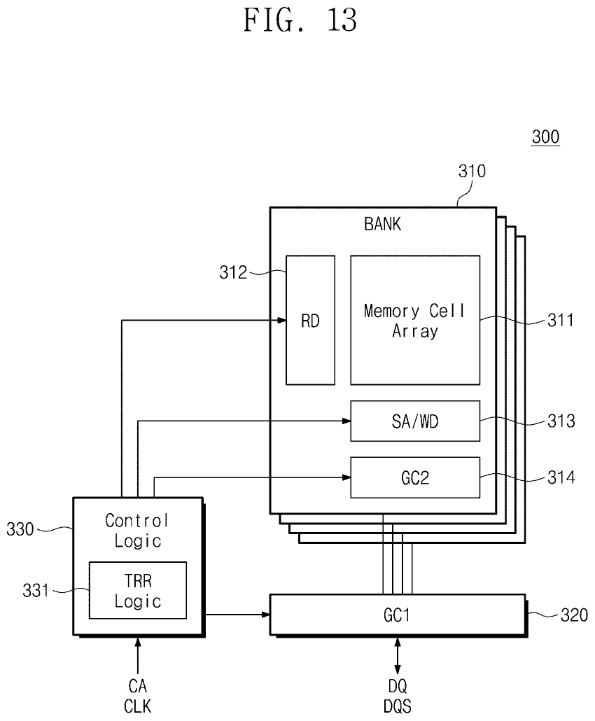

FIG. 12 illustrates an example of color maps generated based on the information of the misalignment MA at the first points, and the information of the misalignment MA at the first and second points. Referring to FIG. 12, a graph G_MPT may be a color map generated based on the information of the misalignment MA at the measured points, that is, the first points. The circles in the block may correspond to the first points. The first points may have a color level corresponding to the information of the misalignment MA.

A graph G_TPT may be a color map generated based on the information of the misalignment MA at the total points, that is, the first points and the second points. The circles in the block may correspond to the first points. The first points may have a color level corresponding to the information of the misalignment MA.

For example, it is illustrated that variation in color level of a particular color as the information of the misalignment MA increases and/or decreases; however, such illustration is provided merely to facilitate understanding. The larger the misalignment MA value, the higher the color level of the first color (e.g., red) may be. The smaller the misalignment MA value, the higher the level of the color of the second color (e.g., blue) may be.

The greater the similarity between the color distributions of the graph G_MPT and the graph G_TPT, the more accurately the information of the misalignment MA at the second points may be regarded as measured. The greater the difference between the color distributions of the graph G_MPT and the graph G_TPT, the less accurately the information of the misalignment MA at the second points may be regarded as measured.

Referring back to FIG. 10, in step S430, the post-processing module 19 may output the graph and the color map. In some implementations, the post-processing module 19 may evaluate the graph and the color, and add score information to be output.

For example, the post-processing module 19 may output the graph, the color map, and/or the score information, to the user. As another example, the post-processing module 19 may output the graph, the color map, and/or the score information to the layout generation module 11. The layout generation module 11 may modify the layout image LO based on the dataset DSET, the graph, the color map, and/or the score information. The modified layout image MLO may be used to manufacture the semiconductor devices on the wafer WAF.

For example, the simulation module 16 may receive other short-range captured images of the semiconductor devices, and repeat the operations described with reference to FIGS. 1 to 12.

FIG. 13 illustrates a dynamic random access memory 300 according to some implementations of the present disclosure. Referring to FIG. 13, the dynamic random access memory 300 may include a plurality of banks (BANK) 310, a first gating circuit (GC1) 320, and a control logic 330.

Each of the plurality of banks 310 may include a memory cell array 311, a row decoder (RD) 312, a sense amplifier and a write driver (SA/WD) 313, and a second gating circuit (GC2) 314.

The memory cell array 311 may include memory cells arranged in rows and columns. The rows of the memory cells may be coupled to word lines, and the columns of the memory cells may be coupled to bit lines.

The row decoder 312 may be coupled to the rows of the memory cells of the memory cell array 311 via the word lines. The row decoder 312 may activate one (e.g., a word line) of the rows of the memory cells of the memory cell array 311 in response to a control of the control logic 330, for example, in response to a row address received from the control logic 330.

The sense amplifier and the write driver 313 may be coupled to the columns of the memory cells of the memory cell array 311 via the bit lines. When a selected row of the memory cells of the memory cell array 311 is activated, in response to the control of the control logic 330, the sense amplifier and the write driver 313 may read data stored in the memory cells of the activated row. When the selected row of the memory cells of the memory cell array 311 is activated, in response to the control of the control logic 330, the sense amplifier and the write driver 313 may write data to the memory cells of the activated row. The sense amplifier and the write driver 313 may include a plurality of sense amplifiers and a plurality of write drivers, respectively, each corresponding to a respective bit line.

The second gating circuit 314 may be connected to the plurality of sense amplifiers and the plurality of write drivers of the sense amplifier and the write driver 313, respectively. The second gating circuit 314 may electrically connect sense amplifiers corresponding to a column address from among the plurality of sense amplifiers with the first gating circuit 320 (e.g., in a read operation), and electrically connect write drivers corresponding to the column addresses from among the plurality of write drivers with the first grating circuit 320 (e.g., in a write operation), in response to the control of the control logic 330, for example, in response to the column address received from the control logic 330.

The first gating circuit 320 may be connected to the plurality of banks 310. In response to the control of the control logic 330, for example, in response to a bank address received from the control logic 330, the first gating circuit 320 may output data received from a bank corresponding to the bank address from among the plurality of banks 310 as the data signal DQ to an external device in synchronization with a data strobe signal DQS (e.g., in the read operation). Similarly, the first gating circuit 320 may output data received from the external device as the data signal DQ to the bank corresponding to the bank address from among the plurality of banks 310 in synchronization with the data strobe signal DQS (e.g., in the write operation).

The control logic 330 may receive a command and an address CA and a clock signal CLK from the external device. The control logic 330 may control the plurality of banks 310 and the first gating circuit 320 in response to the command in CA. The control logic 330 may extract the bank address, the row address, and the column address from the address in CA. The control logic 330 may provide the bank address to the first gating circuit 320, provide the row address to the row decoder 312, and provide the column address to the second gating circuit 314.

The control logic 330 may generate internal clock signal(s) for controlling internal operation timings from the clock signal CLK. The control logic 330 may control the plurality of banks 310 and the first gating circuit 320 in synchronization with the internal clock signal(s). The control logic 330 may generate the data strobe signal DQS output to the external device from the clock signal CLK.

The control logic 330 may receive various control signals from the external device, and output the various control signals to the external device. For example, the plurality of banks 310 may be divided into a plurality of bank groups, and a gating circuit (e.g., a third gating circuit) for selecting the plurality of bank groups may be added. The control logic 330 may further extract a bank group address for selecting the bank group via the third gating circuit from the address of the command and the address CA.

The control logic 330 may include a target row refresh (TRR) logic 331 for performing a target row refresh.

For example, the semiconductor manufacturing system 10 according to some implementations of the present disclosure may be configured to manufacture the dynamic random access memories 300 as the semiconductor devices on the wafer WAF. The simulation module 16 may be configured to measure, predict, and modify misalignments MA that occur during manufacturing semiconductor elements in the dynamic random access memories 300.

For example, the memory cells of the dynamic random access memories 300 include silicon pillars formed on a silicon substrate, and the silicon pillars may function as capacitors of memory cells storing data.

In order to maintain capacitor storage capability as the dimensions of the memory cells and the capacitors shrinks, the height of the silicon pillars functioning as capacitors is increased. As the height of the silicon pillars increases, supporters may be fabricated to support the silicon pillars and prevent collapse. Misalignment between the silicon pillars and the supporters may result in poor connections or collapse of the silicon pillars.

According to some implementations of the present disclosure, the semiconductor manufacturing system 10 may utilize the simulation module 16 to measure, predict, and modify the misalignment MA between the silicon pillars and the supporters in the dynamic random access memories 300. Thus, the yield and the reliability of the dynamic random access memories 300 may be improved.

In the implementations described above, components according to the technical idea of the present disclosure have been described using the terms a first, a second, a third, and the like. However, terms such as the first, the second, the third, and the like are used to distinguish components from each other and do not limit the present disclosure. For example, the terms such as the first, the second, the third, and the like are not intended to imply any particular order or numerical values.

In the implementations described above, components according to implementations of the present disclosure are represented by blocks. The blocks may be implemented in various hardware devices such as an Integrated Circuit (IC), an Application Specific IC (ASIC), a Field Programmable Gate Array (FPGA), a Complex Programmable Logic Device (CPLD), and the like, firmware running on the hardware devices, software such as an application, or a combination of the hardware devices and the software. In addition, the blocks may include circuits composed of semiconductor elements in an IC or circuits registered as an Intellectual Property (IP).

According to implementations of the present disclosure, the information of the misalignment of the second points may be obtained from the information of the misalignment of the first points measured from the image of the semiconductor device, and the misalignment may be modified using the information of the misalignment of the first points and the second points. Accordingly, the operating method of the electronic device configured to manufacture the semiconductor device with reduced error may be provided.

As used herein, the term “at least one of” may refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed, equivalents thereof, as well as claims to be described later. Certain features that are described in this disclosure in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations, one or more features from a combination may in some cases be excised from the combination, and the combination may be directed to a subcombination or variation of a subcombination.

The foregoing is specific implementations for carrying out the present disclosure. The present disclosure will include not only the implementations described above, but also implementations that may be simply changed in design or easily changed. The disclosure will also include techniques that may be readily modified and practiced using implementations. Therefore, the scope of the present disclosure should not be limited to the above-described implementations, but should be defined by the following claims as well as those equivalent to the claims of the present disclosure.

What is claimed is:

1. An operating method of an electronic device configured to manufacture a semiconductor device, the operating method comprising:
receiving at least one image of the semiconductor device;
processing the at least one image, using a first module of the electronic device, to generate processing data including information of a first misalignment at first points on the at least one image; and
calculating, using a second module of the electronic device, information of a second misalignment at second points on the at least one image based on the information of the first misalignment to generate a dataset,
wherein the dataset includes the information of the first misalignment and the information of the second misalignment.

2. The operating method of claim 1, wherein the at least one image includes a plurality of images, and
wherein generating the processing data including the information of the first misalignment includes:
calculating the information of the first misalignment at each of the first points on the plurality of images, respectively.

3. The operating method of claim 2, wherein calculating the information of the first misalignment at each of first points includes:
calculating an average of the information of the first misalignment at the first points across the plurality of images.

4. The operating method of claim 1, wherein one or more first points, from among the first points, having the information of the first misalignment greater than a predetermined threshold value are included in a tail region.

5. The operating method of claim 4, wherein each of the at least one image is divided into a plurality of blocks, and
wherein the tail region including the one or more first points is represented in units of blocks.

6. The operating method of claim 5, wherein generating the processing data including the information of the first misalignment includes:
generating triangles based on the first points in each of blocks in the tail region.

7. The operating method of claim 6, wherein generating the triangles includes:
performing a Delaunay triangulation.

8. The operating method of claim 6, wherein calculating the information of the second misalignment to generate the dataset includes:
detecting third points inside the triangles from among the second points in each of the plurality of blocks; and
performing mapping and interpolation on the third points and the triangles including the third points to calculate information of a third misalignment of the third points.

9. The operating method of claim 8, wherein calculating the information of the third misalignment at the third points includes:
performing an isoparametric mapping on the third points and the triangles including the third points to map the triangles including the third points into quadrilaterals and to map the third points into the quadrilaterals.

10. The operating method of claim 9, wherein calculating the information of the third misalignment at the third points includes:
interpolating information of a first misalignment at first points in the quadrilaterals.

11. The operating method of claim 9, wherein performing the isoparametric mapping on the third points and the triangles includes:
generating a dummy first point in each of the triangles; and
mapping each of the triangles into a quadrilateral using the dummy first point and three first points that are three vertices of each of the triangles.

12. The operating method of claim 6, wherein calculating the information of the second misalignment to generate the dataset includes:
detecting fourth points outside the triangles from among the second points in each of the plurality of blocks; and
setting information of a fourth misalignment at each of the fourth points as information of a first misalignment at a first point closest to each of the fourth point.

13. The operating method of claim 5, comprising:
generating a graph based on a count of the information of the first misalignment and a count of the information of the second misalignment in the tail region.

14. The operating method of claim 1, comprising:
generating a first color map based on the information of the first misalignment; and
generating a second color map based on the information of the first misalignment and the information of the second misalignment.

15. The operating method of claim 1, comprising:
modifying a layout of the semiconductor device using the dataset; and
manufacturing a second semiconductor device using the modified layout.

16. The operating method of claim 1, wherein the first misalignment includes a misalignment between first elements of the semiconductor device and second elements different from the first elements.

17. The operating method of claim 16, wherein the semiconductor device is a dynamic random access memory (DRAM),
wherein the first elements include silicon pillars constituting a capacitor of the DRAM, and
wherein the second elements include supporters for supporting the silicon pillars, and each supporter corresponds to a respective silicon pillar.

18. An operating method of an electronic device configured to manufacture a semiconductor device, the operating method comprising:
receiving images of the semiconductor device;
averaging, using a first module of the electronic device, first misalignment values at a first point across the images to generate an average misalignment value at the first point; and
calculating, using a second module of the electronic device, a second misalignment value at a second point different from the first point across the images based on the average misalignment value.

19. The operating method of claim 18, comprising:
modifying a misalignment of the semiconductor device using the average misalignment value and the second misalignment value.

20. An operating method of an electronic device configured to manufacture a semiconductor device, the operating method comprising:
receiving an image of the semiconductor device;
processing the image, using a first module of the electronic device, to generate processing data including information of a first misalignment at first points on the image; and
calculating, using a second module of the electronic device, information of a second misalignment at second points on the images based on the information of the first misalignment,
wherein the image is divided into a plurality of blocks, the plurality of blocks includes a block of a tail region, wherein the block of the tail region includes one or more first points having the information of the first misalignment greater than a predetermined threshold value,
wherein generating the processing data including the information of the first misalignment includes:
generating triangles using the first points in the block of the tail region, and
wherein calculating the information of the second misalignment includes:
detecting third points inside the triangles from among the second points in each of the plurality of blocks;
performing mapping and interpolation on the third points and the triangles including the third points to calculate information of a third misalignment at the third points;
detecting fourth points outside the triangles from among the second points in each of the plurality of blocks; and
setting information of a fourth misalignment at each of the fourth points as information of a first misalignment at a first point closest to each of the fourth points.
